(19) United States
(12) Patent Application Publication
(10) Pub. No.: US 2004/0150296 A1
(43) Pub. Date: Aug. 5, 2004

(54) Material sensing sensor and module using thin film bulk acoustic resonator

(75) Inventors: Jae Yeong Park, Seoul (KR); Heon Min Lee, Gyeonggi-Do (KR)

Correspondence Address: JONATHAN Y. KANG, ESQ., LEE, HONG, DEGERMAN, KANG & SCHMADEKA, 14th Floor, 801 S. Figueroa Street, Los Angeles, CA, 90017-5554, US

(73) Assignee: LG Electronics Inc.

(21) Appl. No.: 10/764,023

(22) Filed: Jan. 23, 2004

(30) Foreign Application Priority Data
Jan. 24, 2003 (KR) 2003-004879

(51) Int. Cl. H01L 41/08

(52) U.S. Cl. 310/324

(57) ABSTRACT

A material sensing sensor using a thin film bulk acoustic resonator having a compact size and a high material measurement sensitivity is formed together with other material sensing sensors in an array form, and integrated with a signal processor on the same board, to thereby precisely sensing a plurality of materials, and a material sensing module. The material sensing sensor using a thin film bulk acoustic resonator (TFBAR) includes: a first thin film bulk acoustic resonator for generating a first resonant frequency according to the amount and/or thickness of a target material; and a reference thin film bulk acoustic resonator for generating a reference resonant frequency.

### BACKGROUND OF THE INVENTION

1. Field of the Invention

The present invention relates to a material sensing module and, more particularly, to a material sensing module using a thin film bulk acoustic resonator (TFBAR).

2. Description of the Background Art

Recently, interests on a material sensing system for sensing a bio material, a chemical material, an environmental material, a gas material, and the like, are increasing, developments of a sensor for sensing and analyzing various materials are actively ongoing. Especially, a material sensing sensor for sensing a surface adsorption amount of a material by using a property of a piezoelectronic material outputs a resonant frequency deviation according to a target material by using a bulk acoustic wave property of the piezoelectronic material. By measuring the resonant frequency deviation, an adherence amount of a material can be known.

A QCM (Quartz Crystal Microbalance) has been used as a material sensing sensor. The QCM is constructed by slicing quartz crystal along a lattice direction and forming an electrode on the sliced quartz crystal. Since the QCM has the bulk acoustic wave characteristics, it adsorbs a target material to the formed electrode and senses the surface adsorption amount of the target material by a resonant frequency variation value (that is, the resonant frequency deviation).

As the QCM uses voluminous quartz, it is large in size. In addition, a signal processor for processing a signal obtained through a sensing unit of the of the material sensing sensor needs to be formed outside the ACM, the size of the material sensing system is inevitably increased.

As for the QCM, its resonance frequency is varied depending on the thickness of the quartz crystal slice, and the thinner the quartz, the better its sensing sensitivity, but it is not possible to obtain a resonance frequency of greater than hundreds of MHz with quartz.

In addition, the QCM has a single sensing unit for sensing one material. Also, since there is no method for arranging a plurality of sensing units, if a plurality of sensors is installed to sense a plurality of target materials, the volume of the material sensing sensor is too much increased.

The QCM measures a material on the basis of a resonant frequency deviation of a quartz bulk acoustic resonator, or measures an adherence amount of a material by measuring an oscillation frequency deviation according to the resonant frequency deviation of the quartz bulk acoustic resonator. The QCM measuring method requires large-sized, high-priced measuring equipment such as a network analyzer or an oscilloscope.

As stated above, the convention material sensing system has the following problems.

That is, first, because the conventional material sensing system uses the quartz bulk acoustic resonator, the material sensing sensor and the material sensing module are large in size, and since a maximum resonant frequency is low, a measurement sensitivity is low.

Second, since the conventional material sensing system does not have a process method for forming quartz in an array structure, a plurality of material sensing sensors can not be implemented on a single chip, failing to measure a plurality of target materials.

Meanwhile, another thin film bulk acoustic resonator and its fabrication method are also disclosed in a U.S. Pat. No. 6,617,751 issued on Sep. 9, 2003.

### SUMMARY OF THE INVENTION

Therefore, an object of the present invention is to provide a material sensing sensor using a thin film bulk acoustic resonator which has a compact size and a high material measurement sensitivity, is formed in an array form, and integrated with a signal processor on the same board, to thereby precisely sense a plurality of materials, and a material sensing module.

To achieve these and other advantages and in accordance with the purpose of the present invention, as embodied and broadly described herein, there is provided a material sensing sensor using a thin film bulk acoustic resonator (TFBAR) including: a first thin film bulk acoustic resonator for generating a first resonant frequency according to the amount and/or thickness of a target material; and a reference thin film bulk acoustic resonator for generating a reference resonant frequency.

To achieve the above object, there is also provided a material sensing sensor using a thin film bulk acoustic resonator including: a substrate; an upper membrane layer formed at an upper surface of the substrate; a lower membrane layer formed at a lower surface of the substrate; a common lower electrode formed on the lower membrane layer; a piezoelectronic material layer formed on the common lower electrode; first and second upper electrodes formed at prescribed portions on the piezoelectronic material layer; channel patterns formed in a direction corresponding to the first and second upper electrodes and formed on the lower membrane layer by etching the upper membrane layer and the substrate; first and second adsorption layers formed at an upper surface of the lower membrane layer exposed through the channel patterns; and a reactive layer formed on the first adsorption layer.

To achieve the above object, there is also provided a material sensing sensor using a thin film bulk acoustic resonator including: a substrate; an upper membrane layer formed at an upper surface of the substrate; a lower membrane layer formed at a lower surface of the substrate; a lower electrode formed on the lower membrane layer; a piezoelectronic material layer formed on the lower electrode; a pair of upper electrodes formed on the piezoelectronic material layer; a pair of channel patterns formed in a direction corresponding to the pair of upper electrodes and formed by etching the upper membrane layer, the substrate and the lower membrane layer to expose the lower electrode; and a reactive layer formed on the lower electrode exposed through one of the pair of the channel patterns.

To achieve the above object, there is also provided a material sensing sensor using a thin film bulk acoustic resonator including: a substrate; a membrane support layer formed on the substrate; a membrane layer formed on the membrane support layer; a common lower electrode formed on the membrane layer; a piezoelectronic material layer formed on the common lower electrode; first and second upper electrodes formed on the piezoelectronic material layer; a reactive layer formed on the first upper electrode; and a chamber structure formed to expose the reactive layer and a portion of the second upper electrode.

To achieve the above object, there is also provided a material sensing sensor using a thin film bulk acoustic resonator including: a substrate; a membrane support layer formed on the substrate; a common lower electrode formed on the membrane support layer; a piezoelectronic material layer formed on the common lower electrode; first and second upper electrodes formed on the piezoelectronic material layer; a reactive layer formed on the first upper electrode; and a chamber structure formed to expose the reactive layer and a portion of the second upper electrode.

To achieve the above object, there is also provided a material sensing module using a thin film bulk acoustic resonator including: a sensor chip including a plurality of material sensing sensors each having a thin film bulk acoustic resonator generating a measurement resonant frequency according to the amount and/or thickness of a target material and a reference thin film bulk acoustic resonator generating a reference resonant frequency; and a signal processor for mixing the measurement resonant frequency and the reference resonant frequency and measuring the amount and/or thickness of the target material on the basis of a power value of the mixed signal.

The signal processor of the material sensing module using the thin film bulk acoustic resonator includes: a sensing oscillator for outputting a measurement resonant frequency of the measurement thin film bulk acoustic resonator of the material sensing sensor; a reference oscillator for shifting a phase of the resonant frequency of the reference thin film bulk acoustic resonator of the material sensing sensor by 180° to output a reference resonant frequency; a radio frequency (RF) signal mixer for mixing the measurement resonant frequency and the reference resonant frequency; and a power measuring unit for calculating power of the mixed signal.

The signal processor of the material sensing module using the thin film bulk acoustic resonator includes: a sensing oscillator for outputting a measurement resonant frequency of the measurement thin film bulk acoustic resonator; a reference voltage control oscillator (VCO) for shifting a phase of the resonant frequency of the reference thin film bulk acoustic resonator by 180° and outputting the phase-shifted reference resonant frequency; an RF signal mixer for mixing the measurement resonant frequency of the sensing oscillator and the reference resonant frequency of the reference VCO; and a power measuring unit for varying a voltage applied to the reference VCO so as for output power of the mixed signal to be minimized, wherein when the voltage applied to the reference VCO is varied, the adherence amount and thickness of the target material are measured on the basis of the varied voltage value.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a perspective view showing a structure of a material sensing sensor package using a thin film bulk acoustic resonator in accordance with the present invention;

FIG. 2 is a sectional view showing one of material sensing sensors formed in a sensor chip of FIG. 1 in accordance with a first embodiment of the present invention;

FIG. 3 is a graph showing an experimentation of a resonant frequency deviation generated when a target material is adhered to the material sensing sensor of FIG. 2;

FIG. 4 is a sectional view showing a material sensing sensor in accordance with a second embodiment of the present invention;

FIG. 5 is a sectional view showing a material sensing sensor in accordance with a third embodiment of the present invention;

FIG. 6 is a sectional view showing a material sensing sensor in accordance with a fourth embodiment of the present invention;

FIG. 7 is a block diagram showing a first embodiment of a signal processor of the material sensing sensor in accordance with the present invention;

FIG. 8 is a block diagram showing a second embodiment of a signal processor of the material sensing sensor in accordance with the present invention; and

FIGS. 9A and 9B are views showing a portion of the rear side of the sensor chip adopting a material sensing sensor formed in a bulk micro-machining form.

### DETAILED DESCRIPTION OF THE PREFERRED EMBODIMENTS

Reference will now be made in detail to the preferred embodiments of the present invention, examples of which are illustrated in the accompanying drawings.

A material sensing sensor using a thin film bulk acoustic resonator capable of precisely sensing a plurality of materials, and a material sensing module in accordance with a preferred embodiment of the present invention will now be described. In the present invention, a plurality of material sensing sensors, each having a first thin film bulk acoustic resonator generating a first resonant frequency according to the amount and/or thickness of a target material and a reference thin film bulk acoustic resonator generating a reference resonant frequency, are provided to precisely sense a plurality of materials.

FIG. 1 is a perspective view showing a structure of a material sensing sensor package using a thin film bulk acoustic resonator in accordance with the present invention.

As shown in FIG. 1, the material sensing sensor package using the thin film bulk acoustic resonator includes: a sensor chip 100 having a plurality of material sensing sensors 101 disposed therein; and a sensor chip package 200 for packaging the sensor chip 100.

The sensor chip package 200 includes a bonding pad 201 bonded to the plurality of material sensing sensors 101 and an external connection pin 202 connected to the bonding pad.

The construction of the material sensing sensor package using the thin film bulk acoustic resonator will now be described.

First, the sensor chip 100 includes a plurality of material sensing sensors arranged in a lattice form. That is, a plurality of materials can be simultaneously measured through the plurality of material sensing sensors 101, and the plurality of material sensing sensors 101 are constructed in one sensor chip 100. The sensor chip 10 is detachably attached to the sensor chip package, so that the disposable sensor chip 100 can be easily replaced.

The material sensing sensor of the sensor chip 100 is formed as a unit of a pair, and a target material can be individually measured by selectively connecting upper electrodes 5-1 and 5-2 and a common lower electrode 3 of each material sensing sensor.

In the present invention, a pair of TFBARs are used as one material sensing sensor. Namely, of the pair of TFBARs, one is used as a measurement TFBAR sensing an injected target material and the other is used as a reference TFBAR, in order to obtain an absolute measurement value excluding an effect of environment. For example, after a target material to be sensed is injected to the measurement TFBAR, and existence or non-existence of the target material, the amount and thickness of the target material can be sensed on the basis of a resonance frequency of the measurement TFBAR and a resonant frequency of the reference TFBAR.

Meanwhile, as shown in the rear side of the sensor chip, the TFBAR including the upper electrodes 5-1 and 5-2, the common lower electrode 3 and the piezoelectronic material layer 4 is disposed according to a signal processing method, and the sensor chip 100 is bonded to the sensor chip package 200. And then, the upper electrodes 5-1 and 5-2, the common lower electrode 3 and the piezoelectronic material layer 4 are bonded to the bonding pad 201 by using a solder paste.

The formed TFBAR sensor chip package 200 is installed on the same printed circuit board together with the signal processor (Integrated circuit (IC)), to fabricate a material sensing module.

That is, in the present invention, the plurality of material sensing sensors can be constructed in one sensor chip, or the signal processor can be formed on the same substrate together with the sensor chip.

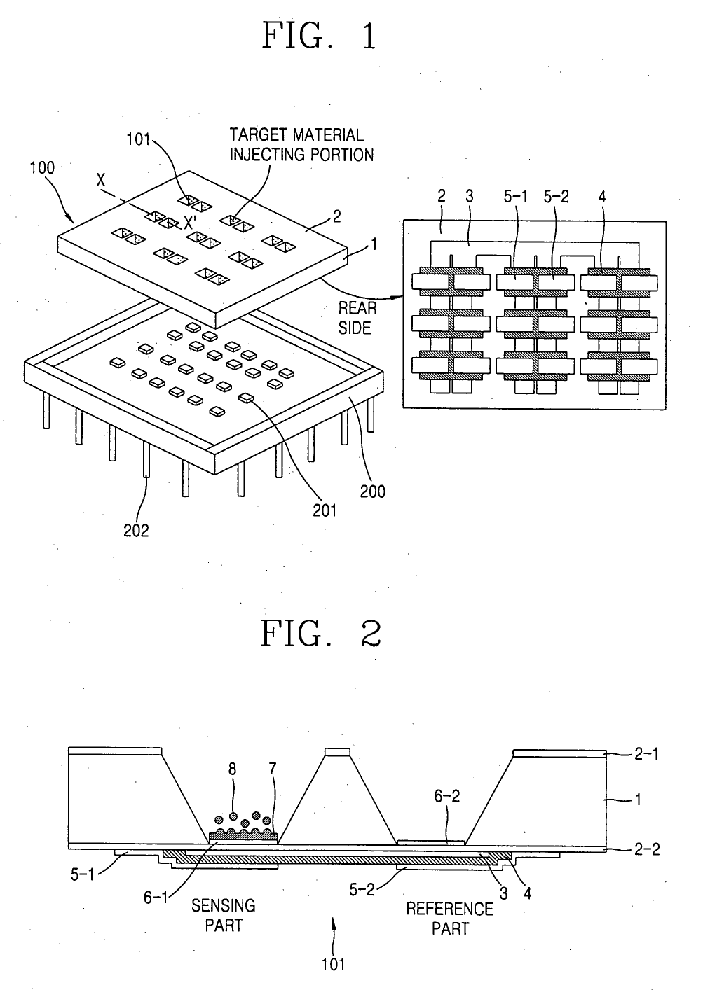

The construction of the material sensing sensor 101 in accordance with a first embodiment of the present invention will now be described with reference to FIG. 2. FIG. 2 is a sectional view showing one of material sensing sensors formed in a sensor chip of FIG. 1 in accordance with a first embodiment of the present invention. As shown in FIG. 2, the material sensing sensor 101 having a pair of TFBARs includes: a substrate 1; an upper membrane layer 2-1 formed at an upper surface of the substrate 1; a lower membrane layer 2-2 formed at a lower surface of the substrate 1; a common lower electrode 3 formed on the lower membrane layer 2-2; a piezoelectronic material layer 4 formed on the common lower electrode 3; first and second upper electrodes 5-1 and 5-2 formed at prescribed portions on the piezoelectronic material layer 4; channel patterns formed in a direction corresponding to the first and second upper electrodes 5-1 an 5-2 and formed on the lower membrane layer 2-2 by etching the upper membrane layer 2-1 and the substrate 1; first and second adsorption layers 6-1 and 6-2 formed at an upper surface of the lower membrane layer 2-2 exposed through the channel patterns; and a reactive layer 7 formed on the first adsorption layer 6-1.

The TFBAR having the reactive layer 7 is a measurement TFBAR (sensing part) for measuring a material, and the TFBAR without the reactive layer 7 is a reference TFBAR (reference part).

One TFBAR includes a lower electrode, a piezoelectronic material layer and an upper electrode.

The membrane layer 2-1 formed at an upper surface of the substrate 1 is irrelevant to the operation of the present invention, and does not interfere an operation of the measurement TFBAR and the reference TFBAR by having a low stress SiNx thin film.

The common lower electrode 3 is formed on the lower membrane layer 2-2-2 formed at a lower surface of the substrate 1, and commonly used by the pair of TFBARs (the measurement TFBAR and the reference TFBAR).

The piezoelectronic material layer 4 is formed on the common lower electrode 3 and made of one of ZnO, AIN and PZT generating a thin film bulk acoustic wave. Since the piezoelectronic material layer 4 is formed by a thin film deposition technique, it can be fabricated very thin, and thus, the measurement TFBAR and the reference TFBAR having a few GHz band of resonant frequency can be easily formed. Namely, by forming the measurement TFBAR and the reference TFBAR having a few GHz band of resonant frequency, a sensitivity of the material sensing sensor adopting the TFBAR can be increased, and the material sensing sensor can be used to measure a bio material such as a DNA (Deoxyribo Nucleic Acid), a cell and protein.

The upper electrodes 5-1 and 5-2 are formed separatively as a pair on the piezoelectronic material layer 4 in order to independently operate the pair of TFBARs (the measurement TFBAR and the reference TFBAR).

Thereafter, the upper membrane layer 2-1 and the substrate 1 are etched by anisotropy in a direction corresponding to the measurement TFBAR and the reference TFBAR to form channel patterns. At this time, only the substrate 1 is completely etched slopingly to expose the lower membrane layer 2-2. The etching process is performed through a micro electro mechanical system bulk micro-machining process.

The adsorption layer 6 is preferably made of metals such as Au, Al, W, Ta, or the like, or a polymer material having a viscosity with an electrode and the reactive layer. A material for the reactive layer 7 can be selected depending on types of a target material. For example, the reactive layer 7 can be used as a reactive material for detecting the prostate cancer, or a material for detecting the stomach cancer.

The reactive layer 7 is to adsorb the target material 8. For example, inn order to provide the target material 8 only to the sensing unit (that is, the measurement TFBAR), a chamber structure is formed at the measurement TFBAR in a manner of exposing the channel pattern or the reactive layer 7.

A resonant frequency of the measurement TFBAR and the reference TFBAR is determined according to the thickness of the lower electrode 8, the piezoelectronic material layer 4, the upper electrodes 5-1 and 5-2 and the lower membrane layer 2-2, and the resonant frequency (fᵣ) is calculated by equation (1) shown below. Herein, a resonant frequency deviation is generated when the target material is deposited or adhered to the reactive layer 7.

$$fr = {\frac{n}{2} [ \frac{{d}_{p}}{{v}_{p}} + \frac{{d}_{m}}{{v}_{m}} ]}^{- 1} \qquad ( 1 )$$

wherein ‘n’ is integer, dₚ is the thickness of the piezoelectronic material layer, vₚ is a propagation velocity of an acoustic wave in the piezoelectronic material layer, dₘ is the thickness of the upper electrode or the lower electrode, and vₘ is a propagation velocity of an acoustic wave in the upper electrode or the lower electrode.

By integrating the sensor chip 100 together with the signal processor on the same printed circuit board through a general semiconductor process, the size of the material sensing module can be considerably reduced.

In the present invention, the material sensing sensor package is formed to be detachable from the material sensing module, and a disposable sensor chip or/and sensor chip package is formed to be detached from or attached to the material sensing module.

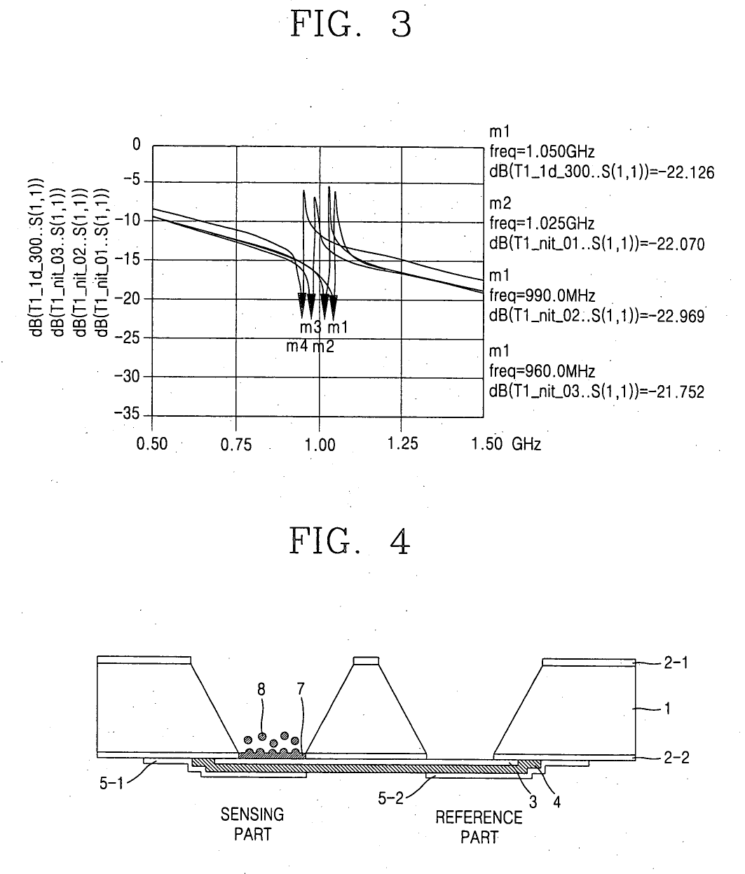

FIG. 3 is a graph showing an experimentation of a resonant frequency deviation generated when a target material is adhered to the material sensing sensor of FIG. 2.

As shown in FIG. 3, a resonant frequency is reduced and deviated by the adhered target material. Since the resonant frequency deviation differs depending on the thickness and mass of the adhered target material, a frequency deviation is measured in advance according to experimentation results (thickness and adhesion amount of various materials) and then an adhesion amount of an actual target material and its thickness can be measured on the basis of the measured frequency deviation. For example, the previously measured frequency deviation is stored in a database, based on which the adhesion amount and thickness of the adhered target material can be accurately measured.

FIG. 4 is a sectional view showing a material sensing sensor in accordance with a second embodiment of the present invention.

As shown in FIG. 4, a material sensing sensor using a thin film bulk acoustic resonator in accordance with a second embodiment of the present invention includes: a substrate 1; an upper membrane layer 2-1 formed at an upper surface of the substrate 1 and a lower membrane layer 2-2 formed at a lower surface of the substrate 1; a lower electrode 3 formed on the lower membrane layer 2-2; a piezoelectronic material layer 4 formed on the lower electrode 3; a pair of upper electrodes 5-1 and 5-2 formed on the piezoelectronic material layer 4; a pair of channel patterns formed in a direction corresponding to the pair of upper electrodes 5-1 and 5-2 and formed by etching the upper membrane layer 2-1, the substrate 1 and the lower membrane layer 2-2 to expose the lower electrode 3; and a reactive layer 7 formed on the lower electrode exposed through one of the pair of the channel patterns.

In the material sensing sensor in accordance with the second embodiment of the present invention, instead of removing the adsorption layer 6 such as in the material sensing sensor of FIG. 2, the substrate 1 is etched up to the membrane layer 2-2 to directly form the reactive layer 7 on the lower electrode 3 of the measurement TFBAR. Accordingly, an inconvenience of additionally forming the adsorption layer 6 such as Au, Al, W, Ta or polymer can be avoided. Herein, the material sensing sensor having the measurement TFBAR in the chamber structure formed by etching by anisotropy the substrate 1 as shown in FIGS. 2 and 4 is called a bulk micro-machining form.

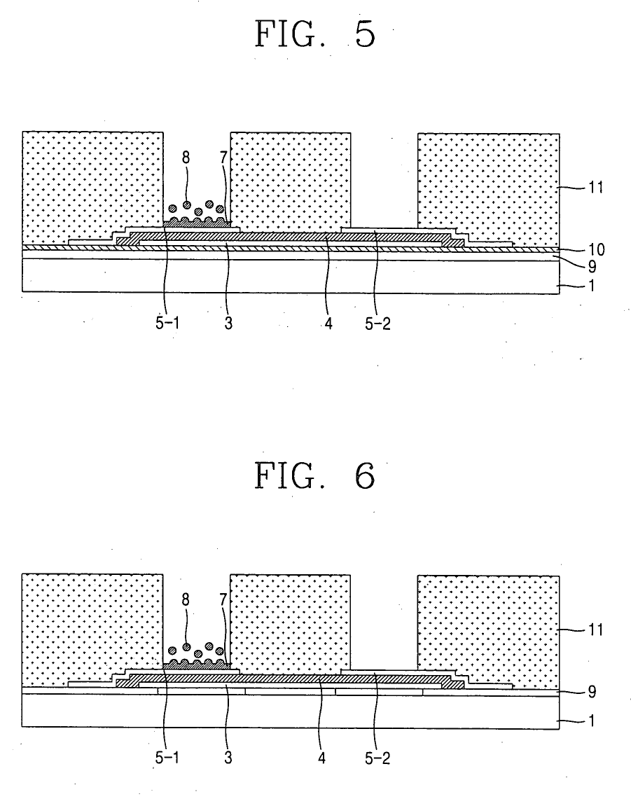

A material sensing sensor in accordance with a third embodiment of the present invention will now be described with reference to FIG. 5.

FIG. 5 is a sectional view showing a material sensing sensor in accordance with a third embodiment of the present invention.

The material sensing sensor in accordance with the third embodiment of the present invention has such a structure that the measurement TFBAR and the reference TFBAR are formed at an upper surface of the substrate 1.

As shown in FIG. 5, a material sensing sensor 110 using a thin film bulk acoustic resonator in accordance with the third embodiment of the present invention includes: a substrate 1; a membrane support layer 9 formed on the substrate 1; a membrane layer 10 formed on the membrane support layer 9; a common lower electrode 3 formed on the membrane layer 10; a piezoelectronic material layer 4 formed on the common lower electrode 3; first and second upper electrodes 5-1 and 5-2 formed on the piezoelectronic material layer 4; a reactive layer 7 formed on the first upper electrode 5-1; and a chamber structure 11 formed to expose the reactive layer and a portion of the second upper electrode.

Since the measurement TFBAR and the reference TFBAR are formed at an upper side of the substrate 1, the membrane support layer 9 is formed at a lower surface of the membrane support layer 9 to provide a space for generating a resonant frequency. The membrane support layer 9 can be formed by using a sacrificial layer. In this respect, the process of forming the sacrificial layer is a known process. Accordingly, in the material sensing sensor in accordance with the third embodiment of the present invention, the reactive layer 7 is formed on the upper electrode 5-1 of the measurement TFBAR (sensing part), so the adsorption layer 6 is not necessary.

The chamber structure 11 for providing the target material 8 to the upper electrode 5-1 of the measurement TFBAR is formed by using PDMS (Poly Dimethyl Siloxane) or a polymer resin. As a matter of course, except for the illustrated chamber structure 11 or the channel pattern, except for the chamber structure 11 or the channel pattern, an additional chamber structure for providing the target material 8 only to the measurement TFBAR by covering the channel pattern portion of the reference TFBAR can be also applied to an upper portion of the sensor chip 100, for a substantial use.

A material sensing sensor in accordance with a fourth embodiment of the present invention will now be described with reference to FIG. 6.

FIG. 6 is a sectional view showing a material sensing sensor in accordance with a fourth embodiment of the present invention.

As shown in FIG. 6, a material sensing sensor using a thin film bulk acoustic resonator in accordance with the fourth embodiment of the present invention includes: a substrate 1; a membrane support layer 9 formed on the substrate 1; a common lower electrode 3 formed on the membrane support layer 9; a piezoelectronic material layer 4 formed on the common lower electrode 3; first and second upper electrodes 5-1 and 5-2 respectively formed on an upper portion of the piezoelectronic material layer 4; a reactive layer 7 formed on the first upper electrode 5-1; and a chamber structure 11 formed to expose the reactive layer and a portion of the second upper electrode.

That is, the material sensing sensor in accordance with the fourth embodiment of the present invention is a structure without the membrane layer 10 of FIG. 4.

The measurement TFBAR and the reference TFBAR can be formed in various structures, and preferably, the measure TFBAR and the reference TFBAR share the piezoelectronic material layer 4 to use it.

Preferably, one of a pair of TFBARs is set as a measurement TFBAR and the reactive layer 7 is formed only at the upper electrode of the measurement TFBAR.

Preferably, electrodes of the measurement TFBAR and the reference TFBAR constituting the material sensing sensor are made of one or more materials selected from the group consisting of Pt, Au, Mo, Al, Cr, Ti, TiN, W, Ta, Ir, IrO₂.

In order to apply the sensor chip adopting the material sensing sensors as shown in FIGS. 5 and 6 to the sensor chip package, a wire bonding technique such as a packing technique of a general semiconductor chip is used. The bonding technique is general and known to a person skilled in the art. Thus, descriptions on a detailed structure of the sensor chip package are omitted.

A sensor chip having a plurality of material sensing sensors through a general semiconductor process can be fabricated and disposed on the printed circuit board to implement a material sensing sensor package capable of simultaneously measuring various materials.

In addition, the signal processor can be formed together with the sensor chip having the material sensing sensors on the same printed circuit board through a general semiconductor process, in order to integrate the signal processor connected to the plurality of material sensing sensors in a single chip.

A method for sensing the adherence amount and thickness of a target material through the material sensing sensors will now be described.

Namely, as for the signal processor desired to be constructed in the present invention, the signal processor of the present invention can include an oscillator of the measurement TFBAR sensing a material and an oscillator of the reference TFBAR, oscillate a signal synchronized with a measurement resonant frequency outputted from the oscillator of the measurement TFBAR and a reference resonant frequency outputted from the oscillator of the reference TFBAR in order to measure a change in radio frequency power generated as the measurement resonant frequency and the reference resonant frequency are mixed, and then, detect existence or nonexistence of a target material and an adherence amount and thickness of the target material on the basis of the measured power value.

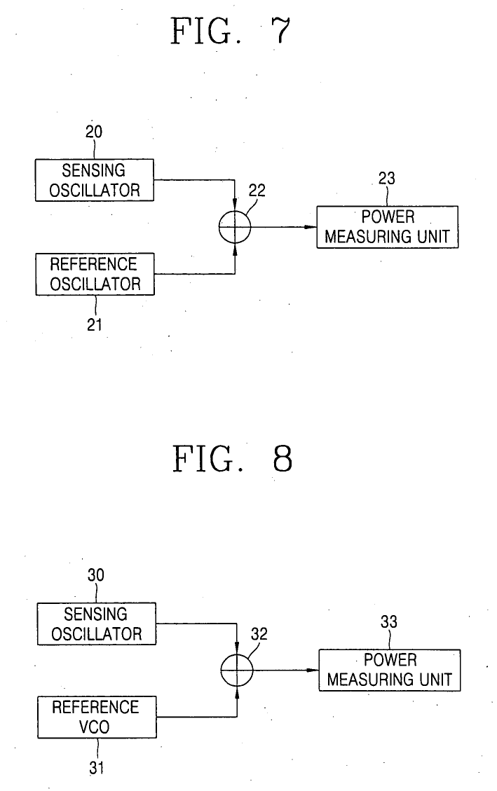

One embodiment of the signal processor will now be described with reference to FIG. 7.

FIG. 7 is a block diagram showing a first embodiment of the signal processor of the material sensing sensor in accordance with the present invention.

As shown in FIG. 7, a signal processor in accordance with the first embodiment 10 includes: a sensing oscillator 20 for outputting a measurement resonant frequency of the measurement TFBAR of the material sensing sensor; a reference oscillator 21 for shifting a phase of the resonant frequency of the reference TFBAR of the material sensing sensor by 180° to output a reference resonant frequency; a radio frequency (RF) signal mixer 22 for mixing the measurement resonant frequency and the reference resonant frequency; and a power measuring unit 23 for calculating power of the mixed signal.

The signal processor in accordance with the first embodiment is operated as follows.

First, when a target material is adhered to the measurement TFBAR, the sensing oscillator 20 outputs a measurement resonant frequency to the RF signal mixer 22. Herein, when the target material is adhered to the measurement TFBAR, a measurement resonant frequency of the measurement TFBAR is varied. The reference oscillator 21 shifts the phase of the resonant frequency generated from the reference TFBAR by 180°, and outputs the phase-shifted reference resonant frequency to the RF signal mixer 22.

Then, the RF signal mixer 22 mixes the reference resonant frequency and the measurement resonant frequency of the measurement TFBAR, and outputs the mixed signal to the power measuring unit 23.

Then, the power measuring unit 23 measures power of the mixed signal. For example, when the reference resonant frequency and the measurement resonant frequency are the same with each other, output power calculated by the power measuring unit 23 is ‘0’.

Meanwhile, if the measurement resonant frequency of the measurement TFBAR is changed according to the adherence amount or thickness of the target material, the output power calculated by the power measuring unit 23 is increased. Thus, by calculating a power value when the target material is adhered on the basis of the output power value when the target material is not adhered, whether the target has been adhered or not, the adherence amount and the thickness can be known.

In addition, when the power measuring unit 23 provides the output power as a digital signal, a main control system (not shown) connected to the material sensing module can easily use the data related to the adherence amount of the material and its thickness.

FIG. 8 is a block diagram showing a second embodiment of a signal processor of the material sensing sensor in accordance with the present invention.

As shown in FIG. 8, the signal processor in accordance with the second embodiment includes: a sensing oscillator 30 for outputting a measurement resonant frequency of the measurement TFBAR; a reference voltage control oscillator (VCO) 31 for shifting a phase of the resonant frequency of the reference TFBAR by 180° and outputting the phase-shifted reference resonant frequency; an RF signal mixer 32 for mixing the measurement resonant frequency of the sensing oscillator 30 and the reference resonant frequency of the reference VCO 35; and a power measuring unit 33 for varying a voltage applied to the reference VCO 31 so as for output power of the mixed signal to be minimized.

Namely, the signal processor in accordance with the second embodiment measures the adherence amount and thickness of the target material on the basis of a voltage applied to the reference VCO.

The operation of the signal processor in accordance with the second embodiment will now be described.

First, when a target material is adhered to the measurement TFBAR, the sensing oscillator 30 outputs a measurement resonant frequency of the measurement TFBAR to the RF signal mixer 32. Herein, when the target material is adhered to the measurement TFBAR, the measurement resonant frequency of the measurement TFBAR is varied. The reference VCO 31 shifts the phase of the resonant frequency generated from the reference TFBAR by 180° and outputs the phase-shifted reference resonant frequency to the RF signal mixer 32.

The RF signal mixer 32 mixes the reference resonant frequency and the measurement resonant frequency of the measurement TFBAR, and outputs the mixed signal to the power measuring unit 33.

The power measuring unit 50 varies a voltage applied to the reference VCO in order to minimize the size of the mixed signal, and measures the adherence amount and thickness of the target material on the basis of the varied voltage value.

For example, when the voltage applied to the reference VCO is controlled to minimize the size of the mixed signal, the voltage applied to the reference VCO is changed according to the amount and/or thickness of the target material adhered to the measurement TFBAR. At this time, the changed voltage value is read, based on which the amount and thickness of the adhered material can be known.

Preferably, the signal processor in accordance with the second embodiment is applied to an analog signal processing system.

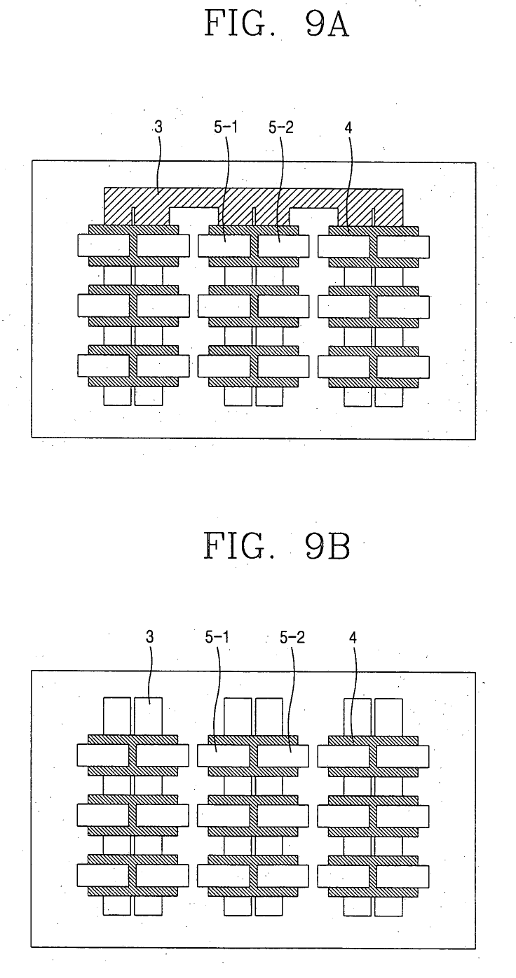

FIGS. 9A and 9B are views showing a portion of the rear side of the sensor chip adopting a material sensing sensor formed in a bulk micro-machining form.

As shown in FIG. 9A, the material sensing module consisting of the sensor chip, the sensor chip package and the signal processor commonly uses the lower electrode 3 of the material sensing sensor 101, and drives a specific material sensing sensor only with the upper electrodes 5-1 and 5-2.

As shown in FIG. 9B, the material sensing module having the sensor chip, the sensor chip package and the signal processor can be formed in a N×N matrix structure to allow for an address designation by separating the lower electrode 3 of the material sensing sensor 101. This can be selectively applied by a developer. As a matter of course, the lower electrodes of the material sensing sensor applied for the sensor chip can be separated or combined.

Accordingly, by implementing the material sensing module using the pair of TFBARs, a sensitivity of a bio sensor, a chemical sensor, an odor sensor, an environmental sensor and a material sensor in accordance with the conventional art can be improved, and since the plurality of materials can be measured simultaneously, time taken for measuring the materials can be reduced, and the material sensing module can be compact in size and integrated.

As so far described, the material sensing module using the TFBAR of the present invention has the following advantages.

That is, for example, since the plurality of material sensing sensors each having a pair of TFBARs formed through a micro-machining process are arranged in a single sensor chip and the single sensor chip and the signal processor are installed on the same printed circuit board, a sensitivity of the material sensing sensor can be enhanced, a plurality of materials can be detected precisely and simultaneously, and the size of the material sensing module can be considerably reduced.

In addition, the single sensor chip of the material sensing module using the TFBAR can be attached to and detached from the sensor chip package, so that the disposable sensor chip can be easily replaced.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. A material sensing sensor using a thin film bulk acoustic resonator (TFBAR) comprising:
a first thin film bulk acoustic resonator for generating a first resonant frequency according to the amount and/or thickness of a target material; and
a reference thin film bulk acoustic resonator for generating a reference resonant frequency.

2. The sensor of claim 1 further comprising:
a first channel pattern formed on the first TFBAR and receiving the target material.

3. The sensor of claim 2 further comprising:
a second channel pattern formed on the reference TFBAR.

4. The sensor of claim 1 comprising:
a substrate;
an upper membrane layer formed at an upper surface of the substrate;
a lower membrane layer formed at a lower surface of the substrate;
a common lower electrode formed on the lower membrane layer;
a piezoelectronic material layer formed on the common lower electrode;
first and second upper electrodes formed at prescribed portions on the piezoelectronic material layer;
channel patterns formed in a direction corresponding to the first and second upper electrodes and formed on the lower membrane layer by etching the upper membrane layer and the substrate;
first and second adsorption layers formed at an upper surface of the lower membrane layer exposed through the channel patterns; and
a reactive layer formed on the first adsorption layer.

5. The sensor of claim 1 comprising:
a substrate;
an upper membrane layer formed at an upper surface of the substrate;
a lower membrane layer formed at a lower surface of the substrate;
a lower electrode formed on the lower membrane layer;
a piezoelectronic material layer formed on the lower electrode;
a pair of upper electrodes formed on the piezoelectronic material layer;
a pair of channel patterns formed in a direction corresponding to the pair of upper electrodes and formed by etching the upper membrane layer, the substrate and the lower membrane layer to expose the lower electrode; and
a reactive layer formed on the lower electrode exposed through one of the pair of the channel patterns.

6. The sensor of claim 1 comprising:
a substrate;
a membrane support layer formed on the substrate;
a membrane layer formed on the membrane support layer;
a common lower electrode formed on the membrane layer;
a piezoelectronic material layer formed on the common lower electrode;
first and second upper electrodes formed on the piezoelectronic material layer;
a reactive layer formed on the first upper electrode; and
a chamber structure formed to expose the reactive layer and a portion of the second upper electrode.

7. The sensor of claim 1 comprising:
a substrate;
a membrane support layer formed on the substrate;
a common lower electrode formed on the membrane support layer;
a piezoelectronic material layer formed on the common lower electrode;
first and second upper electrodes formed on the piezoelectronic material layer;
a reactive layer formed on the first upper electrode; and
a chamber structure formed to expose the reactive layer and a portion of the second upper electrode.

8. The sensor of claim 1 is formed as plural ones, and the plurality of material sensing sensors are disposed in a single sensor chip.

9. The sensor of claim 1 formed as plural ones which are arranged in a lattice form on a single sensor chip.

10. The sensor of claim 9 further comprising:
a sensor chip package having bonding pads connected to the sensor chip, external connection pins connected to the bonding pads and a structure for protecting and supporting the sensor chip.

11. The sensor of claim 1 further comprising:
a signal processor for mixing the first resonant frequency and the reference resonant frequency, and measuring the amount and/or thickness of the target material on the basis of a power value of the mixed signal.

12. The sensor of claim 11, wherein the signal processor comprises:
a sensing oscillator for outputting a first resonant frequency of the first film bulk acoustic resonator of the material sensing sensor;
a reference oscillator for shifting a phase of the resonant frequency of the reference thin film bulk acoustic resonator of the material sensing sensor by 180° to output a reference resonant frequency;
a radio frequency (RF) signal mixer for mixing the first resonant frequency and the reference resonant frequency; and
a power measuring unit for calculating power of the mixed signal.

13. The sensor of claim 11, wherein the signal processor comprises:
a sensing oscillator for outputting a first resonant frequency of the first thin film bulk acoustic resonator;
a reference voltage control oscillator (VCO) for shifting a phase of the resonant frequency of the reference thin film bulk acoustic resonator by 180° and outputting the phase-shifted reference resonant frequency;
an RF signal mixer for mixing the first resonant frequency of the sensing oscillator and the reference resonant frequency of the reference VCO; and
a power measuring unit for varying a voltage applied to the reference VCO so as for output power of the mixed signal to be minimized,
wherein when the voltage applied to the reference VCO is varied, the adherence amount and thickness of the target material are measured on the basis of the varied voltage value.

14. A material sensing module using a thin film bulk acoustic resonator (TFBAR) comprising:
a sensor chip including a plurality of material sensing sensors each having a thin film bulk acoustic resonator generating a measurement resonant frequency according to the amount and/or thickness of a target material and a reference thin film bulk acoustic resonator generating a reference resonant frequency; and
a signal processor for mixing the measurement resonant frequency and the reference resonant frequency and measuring the amount and/or thickness of the target material on the basis of a power value of the mixed signal.

15. The module of claim 14, wherein the signal processor is formed together with the sensor chip on the same substrate.

16. The module of claim 14, wherein a sensor chip package having bonding pads connected to the sensor chip, external connection pins connected to the bonding pads and a structure for protecting and supporting the sensor chip.

17. The module of claim 16, wherein the sensor chip package is installed together with the signal processor on a printed circuit board and detachably attached to the printed circuit board.

18. The module of claim 16, wherein the sensor chip is detached from or attached to the sensor chip package.

19. The module of claim 14, wherein one material sensing sensor in the sensor chip comprises:
a substrate;
an upper membrane layer formed at an upper surface of the substrate;
a lower membrane layer formed at a lower surface of the substrate;
a common lower electrode formed on the lower membrane layer;
a piezoelectronic material layer formed on the common lower electrode;
first and second upper electrodes formed at prescribed portions on the piezoelectronic material layer;
channel patterns formed in a direction corresponding to the first and second upper electrodes and formed on the lower membrane layer by etching the upper membrane layer and the substrate;
first and second adsorption layers formed at an upper surface of the lower membrane layer exposed through the channel patterns; and
a reactive layer formed on the first adsorption layer.

20. The module of claim 14, wherein one material sensing sensor in the sensor chip comprises:
a substrate;
an upper membrane layer formed at an upper surface of the substrate;
a lower membrane layer formed at a lower surface of the substrate;
a lower electrode formed on the lower membrane layer;
a piezoelectronic material layer formed on the lower electrode;
a pair of upper electrodes formed on the piezoelectronic material layer;
a pair of channel patterns formed in a direction corresponding to the pair of upper electrodes and formed by etching the upper membrane layer, the substrate and the lower membrane layer to expose the lower electrode; and
a reactive layer formed on the lower electrode exposed through one of the pair of the channel patterns.

21. The module of claim 14, wherein one material sensing sensor in the sensor chip comprises:
a substrate;
a membrane support layer formed on the substrate;
a membrane layer formed on the membrane support layer;
a common lower electrode formed on the membrane layer;
a piezoelectronic material layer formed on the common lower electrode;
first and second upper electrodes formed on the piezoelectronic material layer;
a reactive layer formed on the first upper electrode; and
a chamber structure formed to expose the reactive layer and a portion of the second upper electrode.

22. The module of claim 14, wherein one material sensing sensor in the sensor chip comprises:
a substrate;
a membrane support layer formed on the substrate;
a common lower electrode formed on the membrane support layer;
a piezoelectronic material layer formed on the common lower electrode;
first and second upper electrodes formed on the piezoelectronic material layer;
a reactive layer formed on the first upper electrode; and
a chamber structure formed to expose the reactive layer and a portion of the second upper electrode.

23. The module of claim 14, wherein the signal processor comprises:
a sensing oscillator for outputting a measurement resonant frequency of the measurement film bulk acoustic resonator of the material sensing sensor;
a reference oscillator for shifting a phase of the resonant frequency of the reference thin film bulk acoustic resonator of the material sensing sensor by 180° to output a reference resonant frequency;
a radio frequency (RF) signal mixer for mixing the measurement resonant frequency and the reference resonant frequency; and
a power measuring unit for calculating power of the mixed signal.

24. The sensor of claim 14, wherein the signal processor comprises:
a sensing oscillator for outputting a measurement resonant frequency of the measurement thin film bulk acoustic resonator;
a reference voltage control oscillator (VCO) for shifting a phase of the resonant frequency of the reference thin film bulk acoustic resonator by 180° and outputting the phase-shifted reference resonant frequency;
an RF signal mixer for mixing the measurement resonant frequency of the sensing oscillator and the reference resonant frequency of the reference VCO; and
a power measuring unit for varying a voltage applied to the reference VCO so as for output power of the mixed signal to be minimized,
wherein when the voltage applied to the reference VCO is varied, the adherence amount and thickness of the target material are measured on the basis of the varied voltage value.
